(19) United States
(12) Patent Application Publication
(10) Pub. No.: US 2025/0194244 A1
(43) Pub. Date: Jun. 12, 2025

(54) THREE DIMENSIONAL STRUCTRUE WITH FD-SOI TRANSISTOR

(71) Applicant: UNITED MICROELECTRONICS CORP., Hsin-Chu City (TW)

(72) Inventors: Purakh Raj Verma, Singapore (SG); Ching-Yang Wen, Singapore (SG); Kai Cheng, Singapore (SG)

(73) Assignee: UNITED MICROELECTRONICS CORP., Hsin-Chu City (TW)

(21) Appl. No.: 18/544,471

(22) Filed: Dec. 19, 2023

(30) Foreign Application Priority Data
Dec. 6, 2023 (TW) 112147424

(51) Int. Cl. H01L 27/12; H01L 21/764; H01L 21/84; H01L 29/66; H01L 29/78

(52) U.S. Cl. CPC H10D 86/201; H01L 21/764; H10D 30/023; H10D 30/611; H10D 30/637; H10D 86/01

(57) ABSTRACT

A three-dimensional structure with an FD-SOI transistor includes a handler wafer, a first device layer and a second device layer stacked in sequence from bottom to top. The first device layer includes a first SOI layer, a first FD-SOI transistor and a first back gate. The first SOI layer includes a first front side and a first back side. The first FD-SOI transistor is disposed on the first front side. The first back gate is disposed on the first back side. The second device layer includes a second SOI layer, a second FD-SOI transistor and a second back gate. The second SOI layer includes a second front side and a second back side. The second FD-SOI transistor is disposed on the second front side. The second back gate is disposed on the second back side.

### BACKGROUND OF THE INVENTION

### 1. Field of the Invention

The present invention relates to a fully depleted silicon-on-insulator (FD-SOI) transistor, and particularly to a three-dimensional (3D) structure with an FD-SOI transistor.

### 2. Description of the Prior Art

The market has a strong demand for advanced semiconductor processes. From the latest 5G mobile communication technology to the new generation of semiconductor applications such as artificial intelligence and smart cars that have been extremely popular recently.

Most new applications depend on new semiconductor processes to enable terminals, and make terminal application modules to achieve smaller size, lower power consumption, and lower cost.

5G mobile communication technology is committed to faster transmission speeds, massive information transmission and low latency, the demand for process technology is greater than ever. To improve product performance to a higher level can start from two directions: process shrinkage and advanced packaging. If process level is scaled down, cost of semiconductor equipment increases, yields and technical difficulties will also raise. Therefore, it is currently a mainstream to use advanced package to improve performance, process costs and physical limitations.

### SUMMARY OF THE INVENTION

In view of this, the present invention provides a 3D structure with FD-SOI transistors, which reduces the size of a chip by stacking wafers.

According to a preferred embodiment of the present invention, a 3D structure with an FD-SOI transistor includes a handler wafer, a first device layer and a second device layer stacked from bottom to top in sequence, wherein the first device layer includes a first silicon-on-insulator (SOI) layer. The first SOI layer includes a first front side and a first back side. A first FD-SOI transistor is disposed on the first front side. A first back gate is disposed on the first back side. The second device layer includes a second SOI layer. The second SOI layer includes a second front side and a second back side. A second FD-SOI transistor is disposed on the second front side. A second back gate is disposed on the second back side. A first metal interconnection set electrically connects to a source of the first FD-SOI transistor and a source of the second FD-SOI transistor. A second metal interconnection set electrically connects to a drain of the first FD-SOI transistor and a drain of the second FD-SOI transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 6 depict a fabricating method of a three-dimensional (3D) structure with a fully depleted silicon-on-insulator (FD-SOI) transistor according to a preferred embodiment of the present invention, wherein:

FIG. 1 depicts a handler wafer with an FD-SOI transistor thereon;

FIG. 2 is a fabricating stage in continuous of FIG. 1;

FIG. 3 is a fabricating stage in continuous of FIG. 2;

FIG. 4 is a fabricating stage in continuous of FIG. 3;

FIG. 5 is a fabricating stage in continuous of FIG. 4; and

FIG. 6 is a fabricating stage in continuous of FIG. 5.

FIG. 7 depicts a fabricating method of a 3D structure with an FD-SOI transistor according to another preferred embodiment of the present invention.

### DETAILED DESCRIPTION

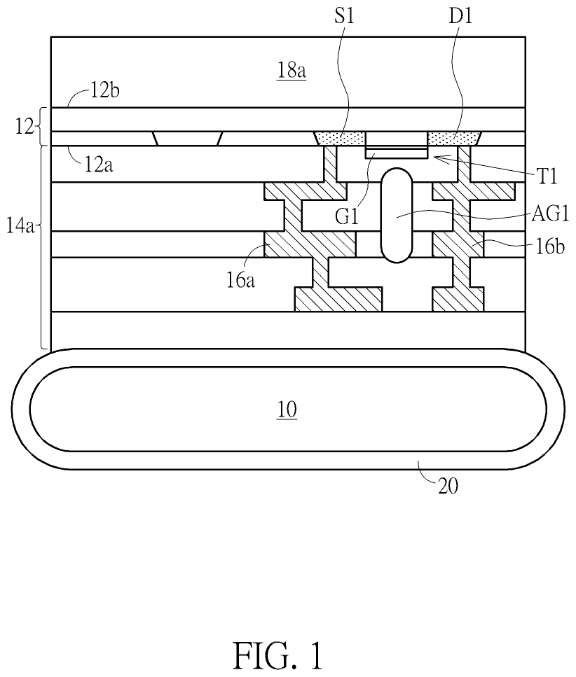

FIGS. 1 to 6 depict a fabricating method of a three-dimensional (3D) structure with a fully depleted silicon-on-insulator (FD-SOI) transistor according to a preferred embodiment of the present invention.

As shown in FIG. 1, a handler wafer 10 and a first silicon-on-insulator (SOI) layer 12 are provided. The handler wafer 10 may be a high-resistance silicon wafer, an insulating material, or a trap-rich substrate. The first SOI layer 12 includes a first front side 12a and a first back side 12b. The first front side 12a is opposite to the first back side 12b. A first FD-SOI transistor T1 is disposed on the first front side 12a. A first dielectric layer 14a covers and contacts the first front side 12a and the first FD-SOI transistor T1. A first air gap AG1 is embedded in the first dielectric layer 14a and is disposed directly above the gate G1 of the first FD-SOI transistor T1. A first conductive line 16a is embedded in the first dielectric layer 14a and electrically connected to a source S1 of the first FD-SOI transistor T1. A second conductive line 16b is embedded in the first dielectric layer 14a and electrically connected to a drain D1 of the first FD-SOI transistor T1. A low-resistance handler wafer 18a contacts the first back side 12b. Then, a silicon oxide layer 20 is formed to encapsulate the wafer 10. Next, the first dielectric layer 14a and the silicon oxide layer 20 are brought into contact. Next, the first dielectric layer 14a and the silicon oxide layer 20 are heated to bond the first dielectric layer 14a to the silicon oxide layer 20.

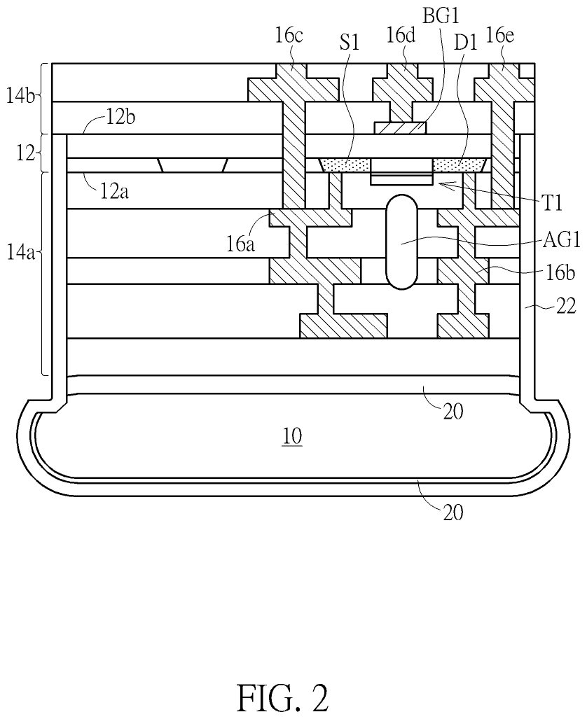

As shown in FIG. 2, the edge of the handler wafer 10 is trimmed. Later, a silicon oxide layer 22 is formed to cover the silicon oxide layer 20, both sides of the first dielectric layer 14a and the low-resistance handler wafer 18a. After that, the low-resistance handler wafer 18a is removed to expose the first side 12b of the first SOI layer 12. Then, a first back gate BG1 is formed on the first back side 12b. Thereafter, a second dielectric layer 14b is formed to cover the first back side 12b. A third conductive line 16c, a fourth conductive line 16d and a fifth conductive line 16e are embedded in the second dielectric layer 14b. The third conductive line 16c and the fifth conductive line 16e penetrate the first SOI layer 12. The third conductive line 16c contacts the first conductive line 16a, and the fifth conductive line 16e contacts the second conductive line 16b. The fourth conductive line 16d contacts the first back gate BG1.

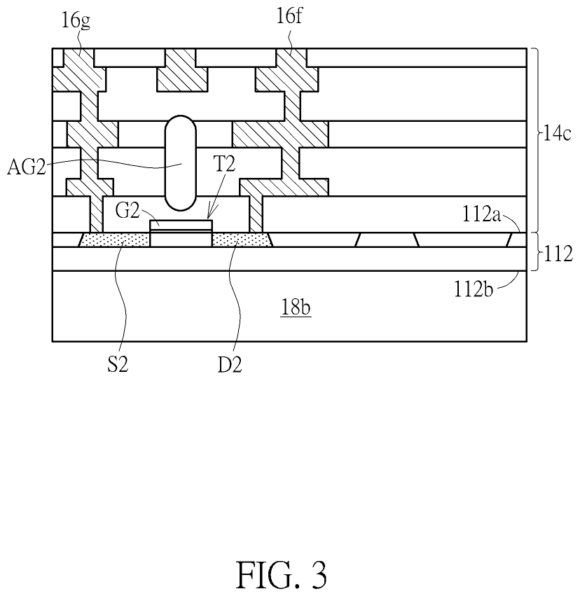

As shown in FIG. 3, a second SOI layer 112 is provided. The second SOI layer 112 includes a second front side 112a and a second back side 112b. The second front side 112a is opposite to the second back side 112b. A second FD-SOI transistor T2 is disposed on the second front side 112a. A third dielectric layer 14c covers and contacts the second front side 112a and the second FD-SOI transistor T2. A second air gap AG2 is embedded in the third dielectric layer 14c and is disposed directly above the gate G2 of the second FD-SOI transistor T2. A sixth conductive line 16f is embedded in the third dielectric layer 14c and electrically connected to a source S2 of the second FD-SOI transistor T2. A seventh conductive line 16g is embedded in the third dielectric layer 14c and electrically connected to a drain D2 of the second FD-SOI transistor T2. A low-resistance handler wafer 18b contacts the second back side 112b.

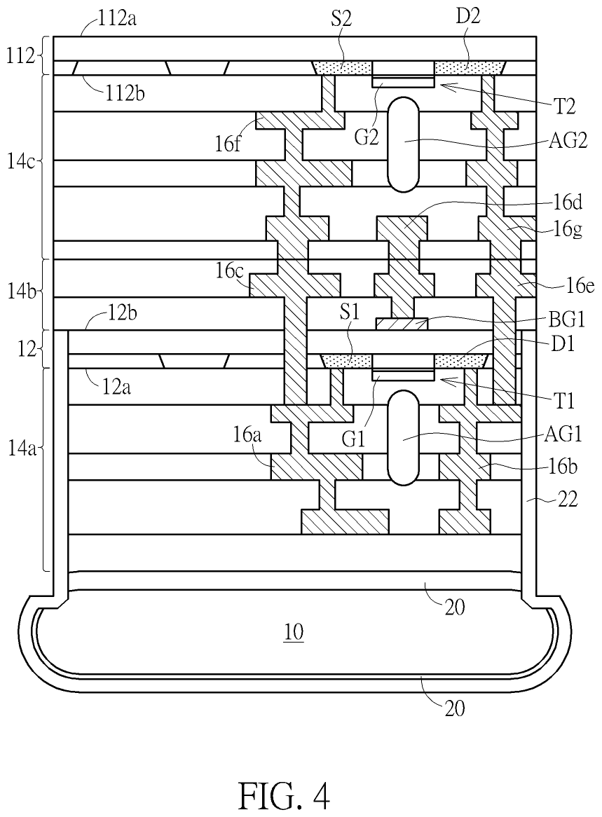

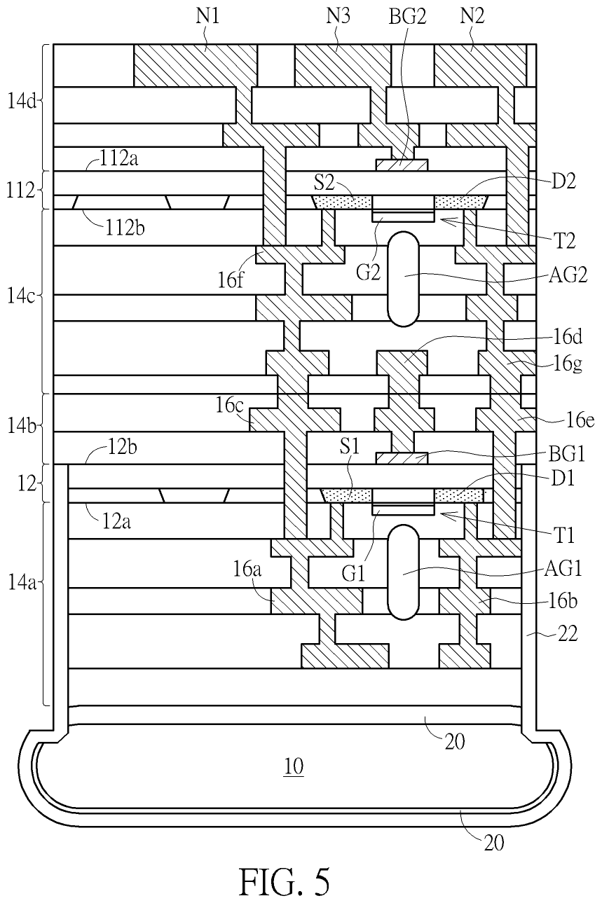

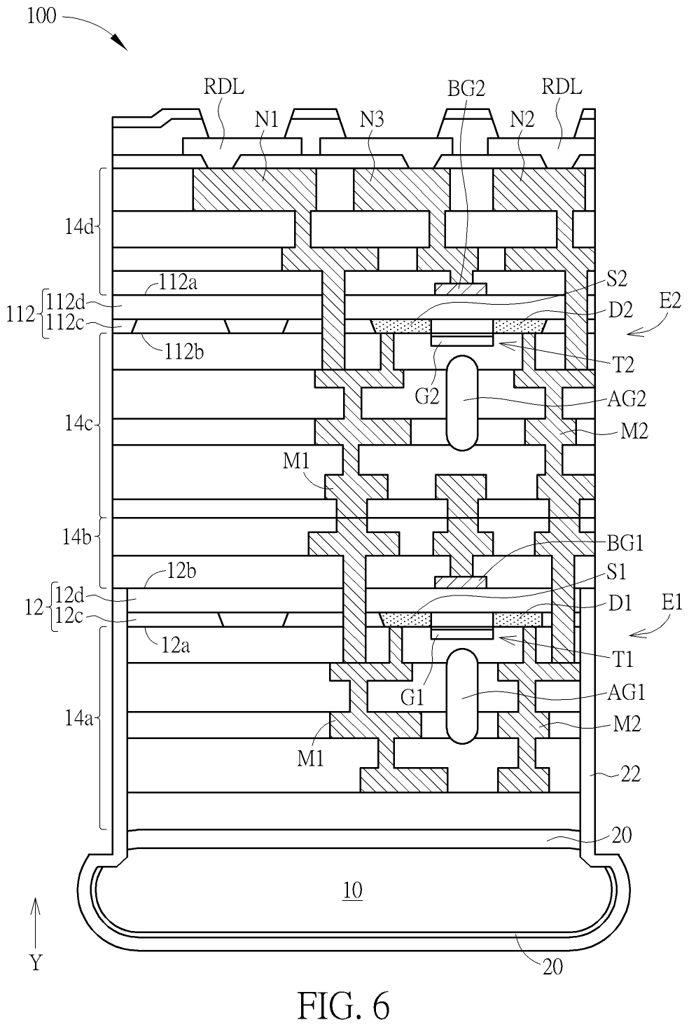

As shown in FIG. 4, the third dielectric layer 14c and the second dielectric layer 14b are bonded by contacting the third dielectric layer 14c to the second dielectric layer 14b and heating the third dielectric layer 14c and the second dielectric layer 14b. Then, the low-resistance handler wafer 18b is removed. As shown in FIG. 5, a second back gate BG2 is formed and disposed on the second back side 112b. Next, a fourth dielectric layer 14d is formed to cover the second back side 112b. A first external circuit N1, a second external circuit N2 and a third external circuit N3 are embedded in the fourth dielectric layer 14d. The first external circuit N1 contacts and electrically connects to the sixth conductive line 16f. The second external circuit N2 contacts and electrically connects to the seventh conductive line 16g. The third external circuit N3 contacts the second back gate BG2. As shown in FIG. 6, numerous redistribution line layers RDL are formed to electrically connect the first external circuit N1, the second external circuit N2 and the third external circuit N3. Now, a 3D structure with an FD-SOI transistor 100 of the present invention is completed.

As shown in FIG. 6, a 3D structure with an FD-SOI transistor 100 includes a handler wafer 10, a first device layer E1 and a second device layer E2 stacked from bottom to top in sequence. The first device layer E1 includes a first SOI layer 12, a first FD-SOI transistor T1 and a first back gate BG1. The first SOI layer 12 includes a first front side 12a and a first back side 12b. The first front side 12a and the first back side 12b are opposite to each other. The first FD-SOI transistor T1 is disposed on the first front side 12a. A first back gate BG 1 is disposed on the first back side 12b. In details, the first SOI layer 12 includes a first silicon layer 12c and a first silicon oxide layer 12d. The first silicon layer 12c contacts the first silicon oxide layer 12d. The first front side 12a is a top surface of the first silicon layer 12c, and the first back side 12b is a bottom surface of the first silicon oxide layer 12d. The thickness of the first silicon oxide layer 12d is preferably between 200 and 500 angstroms. The second device layer E2 includes a second SOI layer 112, a second FD-SOI transistor T2 and a second back gate BG2. The second SOI layer 112 includes a second front side 112a and a second back side 112b. The second front side 112a and the second back side 112b are opposite to each other. The second FD-SOI transistor T2 is disposed on the second side 112a. A second back gate BG 2 is disposed on the second back side 112b. In details, the second SOI layer 112 includes a second silicon layer 112c and a second silicon oxide layer 112d. The second silicon layer 112c contacts the second silicon oxide layer 112d. The second front side 112a is a top surface of the second silicon layer 112c, and the second back side 112b is a bottom surface of the second silicon oxide layer 112d. The thickness of the second silicon oxide layer 112d is preferably between 200 and 500 angstroms.

A first dielectric layer 14a covers and contacts the first front side 12a, and a second dielectric layer 14b covers and contacts the first back side 14b. A third dielectric layer 14c covers and contacts the second front side 112a and a fourth dielectric layer 14d covers and contacts the second back side 112b. The second dielectric layer 14b bonds to the third dielectric layer 14c. The first dielectric layer 14a, the second dielectric layer 14b, the third dielectric layer 14c and the fourth dielectric layer 14d are preferably made of insulating materials, such as silicon oxide, silicon nitride or silicon oxynitride. A first metal interconnection set M1 electrically connects to a source S1 of the first FD-SOI transistor T1 and a source S2 of the second FD-SOI transistor T2. A second metal interconnection set M2 electrically connects to a drain D1 of the first FD-SOI transistor T1 and a drain D2 of the second FD-SOI transistor T2. A first external circuit N1 electrically connects to first metal interconnection set M1. A second external circuit N2 electrically connects to the second metal interconnection set M2. The third external circuit N3 contacts the second back gate BG2. The first metal interconnection set M1 and the second metal interconnection set M2 are embedded in the first dielectric layer 14a, the second dielectric layer 14b, and the third dielectric layer 14c. The first external circuit N1, the second external circuit N2 and the third external circuit N3 are embedded in the fourth dielectric layer 14d. Numerous redistribution line layers RDL are disposed on the fourth dielectric layer 14d, and each of the redistribution line layers RDL is respectively electrically connected to the first external circuit N1, the second external circuit N2, and the third external circuit N3.

In addition, the handler wafer 10 can be a high-resistance silicon wafer, an insulating material, or a trap-rich substrate. The aforementioned insulating material can be glass, quartz, silicon nitride or other insulating material. Moreover, the resistivity of the insulating material is preferably greater than 10⁹ ohm-meters, which means that the insulating material is preferably a material with a resistivity greater than 10⁹ ohm-meters. Generally, the resistance of wafers used in the semiconductor field is usually between 30 and 200 ohm-meters. However, the resistivity of the handler wafer 10 of the present invention is preferably greater than 10⁹ ohm-meters. Furthermore, the width of the handler wafer 10 is preferably greater than the width of the first dielectric layer 14a.

Moreover, the first back gate BG1 and the second back gate BG2 respectively include titanium nitride, doped polysilicon or other conductive materials. The silicon oxide layer 20 encapsulates and contacts the handler wafer 10. The silicon oxide layer 20 bonds to the first dielectric layer 14a. The silicon oxide layer 22 contacts the sidewall of the first dielectric layer 14a, and the silicon oxide layer 20 and the silicon oxide layer 22 are connected.

Furthermore, a first air gap AG1 is embedded in the first dielectric layer 14a and the first air gap AG1 is disposed directly above the gate G1 of the first FD-SOI transistor T1. A second air gap AG2 is embedded in the third dielectric layer 14c and the second air gap AG2 is disposed directly above the gate G2 of the second FD-SOI transistor T2. A direction Y is perpendicular to the top surface of the handler wafer 10. Along the direction Y, the first air gap AG1 is aligned with the second air gap AG2. The first FD-SOI transistor T1 and the second FD-SOI transistor T2 can respectively serve as a low-noise amplifier, a switching element or a power amplifier, and their functions can be the same or different.

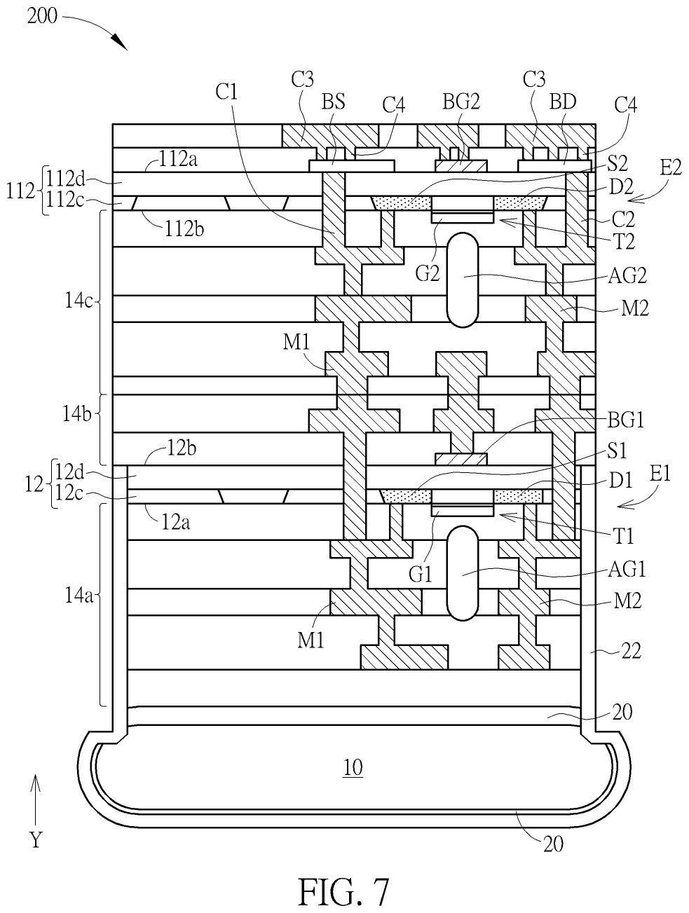

FIG. 7 depicts a fabricating method of a 3D structure with an FD-SOI transistor according to another preferred embodiment of the present invention, wherein elements which are substantially the same as those in the embodiment of FIG. 6 are denoted by the same reference numerals; an accompanying explanation is therefore omitted.

The 3D structure with an FD-SOI transistor 200 in FIG. 7 has a heat dissipation structure. The heat dissipation structure includes a back source BS and a back drain BD. The back source BS and the back drain BD are disposed on the second back side 112b, and the back source BS and the back drain BD contact the second silicon oxide layer 112d. The back source BS at least partially overlaps the source S2 of the second FD-SOI transistor T2. The back drain BD at least partially overlaps the drain D2 of the second FD-SOI transistor T2. Moreover, the back source BS electrically connects to the first metal interconnection set M1 by the through via C1, and the back drain BD electrically connects to the second metal interconnection set M2 by the through via C2. Therefore, the back source BS electrically connects the source S1 and the source S2, and the back drain BD electrically connects to the drain electrode D1 and the drain electrode D2. The through via C1 and through via C2 penetrate the second SOI layer 112. Since the back source BS and the back drain DB respectively partially overlap the source S2 and drain D2 of the second FD-SOI transistor T2, the heat generated by the source S2 and the drain D2 can be transmitted to outside through the back source BS and the back drain BD. Furthermore, a conductive plug C4 and a conductive pad C3 can be respectively provided on the back source BS and the back drain BD to achieve better heat dissipation. Other elements of the 3D structure with an FD-SOI transistor 200 are the same as those of the 3D structure with an FD-SOI transistor 100, and therefore the description are omitted.

The present invention stacks wafers with FD-SOI transistors to form a 3D structure. In this way, size of the devices can be reduced and process costs can be decreased.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A three-dimensional (3D) structure with a fully depleted silicon-on-insulator (FD-SOI) transistor, comprising:
a handler wafer, a first device layer and a second device layer stacked from bottom to top in sequence, wherein the first device layer comprises:
a first silicon-on-insulator (SOI) layer comprising a first front side and a first back side;
a first FD-SOI transistor disposed on the first front side; and
a first back gate disposed on the first back side;
wherein the second device layer comprises:
a second SOI layer comprising a second front side and a second back side;
a second FD-SOI transistor disposed on the second front side; and
a second back gate disposed on the second back side;
a first metal interconnection set electrically connecting to a source of the first FD-SOI transistor and a source of the second FD-SOI transistor; and
a second metal interconnection set electrically connecting to a drain of the first FD-SOI transistor and a drain of the second FD-SOI transistor.

2. The 3D structure with an FD-SOI transistor of claim 1, wherein the first SOI layer comprises a first silicon layer and a first silicon oxide layer, the first silicon layer contacts the first silicon oxide layer, the first front side is a top surface of the first silicon layer, and the first back side is a bottom surface of the first silicon oxide layer.

3. The 3D structure with an FD-SOI transistor of claim 1, wherein the second SOI layer comprises a first second layer and a second silicon oxide layer, the second silicon layer contacts the second silicon oxide layer, the second front side is a top surface of the second silicon layer, and the second back side is a bottom surface of the second silicon oxide layer.

4. The 3D structure with an FD-SOI transistor of claim 1, further comprising:
a first dielectric layer covering and contacting the first front side;
a second dielectric layer covering and contacting the first back side;
a third dielectric layer covering and contacting the second front side; and
a fourth dielectric layer covering and contacting the second back side; wherein the second dielectric layer is bonded to the third dielectric layer.

5. The 3D structure with an FD-SOI transistor of claim 4, further comprising a third silicon oxide layer covering and contacting the handler wafer, and the third silicon oxide layer is bonded to the first dielectric layer.

6. The 3D structure with an FD-SOI transistor of claim 4, further comprising a fourth silicon oxide layer contacting a sidewall of the first dielectric layer.

7. The 3D structure with an FD-SOI transistor of claim 4, further comprising a first external circuit and a second external circuit respectively embedded in the fourth dielectric layer, wherein the first external circuit electrically connects to the first metal interconnection set, and the second external circuit electrically connects to the second metal interconnection set.

8. The 3D structure with an FD-SOI transistor of claim 4, further comprising a third external circuit contacting the second back gate, wherein the third external circuit is embedded in the fourth dielectric layer.

9. The 3D structure with an FD-SOI transistor of claim 1, further comprising:
a first air gap embedded in the first dielectric layer and disposed directly above a first gate of the first FD-SOI transistor; and
a second air gap embedded in the third dielectric layer and disposed directly above a second gate of the second FD-SOI transistor.

10. The 3D structure with an FD-SOI transistor of claim 1, wherein the first back gate and the second back gate respectively comprise titanium nitride or doped polysilicon.
